(19) United States
(12) Patent Application Publication
(10) Pub. No.: US 2007/0195619 A1
(43) Pub. Date: Aug. 23, 2007

(54) Integrated circuit memory devices having multi-bit normal memory cells and single-bit redundant memory cells therein

(75) Inventors: Hyoung-seub Rhie, Gyeonggi-do (KR); Yeong-taek Lee, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/647,672

(22) Filed: Dec. 29, 2006

(30) Foreign Application Priority Data
Feb. 21, 2006 (KR) 2006-16689

(51) Int. Cl. G11C 7/00; G11C 29/00

(52) U.S. Cl. 365/200

(57) ABSTRACT

A memory device includes a first memory array having a plurality of rows and columns of multi-bit DRAM cells therein. A redundant memory array is also provided having a plurality of single-bit memory cells therein. These single-bit memory cells are configured to support replacement of a first plurality of multi-bit memory cells within the first memory array, in response to detecting at least one defective multi-bit memory cell within the first plurality of multi-bit memory cells. This first plurality of multi-bit memory cells may be a column or row of multi-bit memory cells containing at least one defective multi-bit memory cell therein.

### REFERENCE TO PRIORITY APPLICATION

This application claims priority to Korean Application No. 2006-16689, filed Feb. 21, 2006, the disclosure of which is hereby incorporated herein by reference.

### FIELD OF THE INVENTION

The present invention relates to semiconductor memory devices and, more particularly, to semiconductor memory devices having multi-level memory cells therein.

### BACKGROUND OF THE INVENTION

Typical dynamic random access memories (DRAMs) include a plurality of memory cells therein which store single bit data (e.g., a bit value of 0 or 1). Multi-level DRAMs include a plurality of memory cells which store m-bit data. Thus, multi-level DRAMs may have m times larger storage capacity than typical DRAMs. FIG. 1 is a circuit diagram of a conventional multi-level DRAM having a plurality of multi-level cells (MLCs), each storing 2-bit data. Referring to FIG. 1, an MLC array 100 including two bitlines BL and BLB is divided into three blocks MA, SB, and MB. A plurality of wordlines WL0, WL1, . . . , WL2ₘ₋₂, and WL2ₘ₋₁ are provided to the block MA. The block MA includes a plurality of MLCs, which are respectively located in the space between the intersections of the wordlines WL0, WL1, . . . , WL2ₘ₋₂, and WL2ₘ₋₁ and the bitlines BL and BLB. In the block MA, a total of m MLCs are connected to each of the bitlines BL and BLB. A plurality of wordlines WL2ₘ₊₁, WL2ₘ₊₂, . . . , WL3ₘ₋₂, and WL3ₘ₋₁ are provided to the block MB. The block MB includes a plurality of MLCs, which are respectively located in the space between the intersections of the wordlines WL2ₘ₊₁, WL2ₘ₊₂, . . . , WL3ₘ₋₂, and WL3ₘ₋₁ and the bitlines BL and BLB. In the block MB, a total of m/2 MLCs are connected to each of the bitlines BL and BLB.

In the block SB, each of the bitlines BL and BLB is split by a transmission gate T1, which is controlled by a gate selection signal TG. For convenience, the bitlines BL and BLB in the block MA will now be referred to as bitlines BL_A and BLB_A, and the bitlines BL and BLB in the block MB will now be referred to as bitlines BL_B and BLB_B. A first sense amplifier SA_{L} is connected to the bitlines BL_A and BLB_A, and a second sense amplifier SA_{M} is connected to the bitlines BL_B and BLB_B. The first sense amplifier SA_{L} is enabled by a first sensing signal Φ_{L}, and the second sense amplifier SA_{M} is enabled by a second sensing signal Φ_{M}. A coupling capacitor Cc is connected between the bitline BL_A and the bitline BLB_B, and another coupling capacitor Cc is connected between the bitline BLB_A and the bitline BL_B. The first and second sense amplifiers SA_{L} and SA_{M} are connected to a plurality of data lines DB_{L}, D_{L}, DB_{M}, and D_{M} via a plurality of column select transistors CST1 that are controlled by a column selection signal CS.

Each of the MLCs in the MLC array 100 includes an N-channel MOS transistor and a capacitor Cs. The capacitor Cs may store bit data corresponding to one of a plurality of voltages presented in Table 1 below. In Table 1, reference character Vca indicates a power supply voltage of a memory cell array block.

TABLE 1

| | (MSB LSB) |
|---|---|
| 0 V | (0 0) |
| Vca/3 | (0 1) |
| 2Vca/3 | (1 0) |
| Vca | (1 1) |

The operation of the MLC array 100, and particularly, an operation for sensing data stored in an MLC 101, which is located in the space between the intersections of the wordline WL2ₘ₊₁ and the bitline BL_B, will now be described in detail with reference to FIG. 1. It will be assumed that the data stored in the MLC 101 is “10”. When the gate selection signal TG becomes logic high, the bitline BL_A and the bitline BL_B are connected, and the bitline BLB_A and the bitline BLB_B are connected. The bitlines BL_A, BL_B, BLB_A, and BLB_B are all precharged to a voltage Vca/2 by a bitline equalizer (not shown).

Thereafter, when the wordline WL2ₘ₊₁ is activated in response to a row address signal, charge stored in a capacitor Cs of the MLC 101 is shared with the bitline BL_B. In response, the voltage of the bitline BL_B is boosted by ΔV. At this time, the bitline BLB_B is maintained at the voltage Vca/2.

When the gate selection signal TG becomes logic low, the bitline BL_A and the bitline BL_B are disconnected from each other, and the bitline BLB_A and the BLB_B are disconnected from each other. Thereafter, when the second sensing signal Φ_{M} is applied, the second sense amplifier SA_{M} senses the most significant bit (MSB) of the data stored in the MLC 101. Then, the bitline BL_B is boosted to the voltage Vca, and the bitline BLB_B is dropped to 0 V.

Thereafter, because the bitline BL_B is coupled to the bitline BLB_A by the coupling capacitor Cc, the bitline BLB_A is boosted from the voltage Vca/2 by ΔV, whereas the bitline BL_A is dropped from the voltage Vca/2 by ΔV by the other coupling capacitor Cc. When the first sensing signal Φ_{L} is applied, the first sense amplifier SA_{L} senses the voltages of the bitline BL_A and the bitline BLB_A. Then, the bitline BL_A is dropped to 0 V, and the bitline BLB_A is boosted to the voltage Vca.

When a column selection signal CS having a logic high level is applied, the bitline BL_B, which has the voltage Vca, is connected to the data line D_{M}, the bitline BLB_B, which has a voltage of 0 V, is connected to the data line DB_{M}, the bitline BL_A, which has a voltage of 0 V, is connected to the data line D_{L}, and the bitline BLB_A, which has the voltage Vca, is connected to the data line DB_{L}. Then, an MSB value of 1 stored in the MLC 101 is read out by the data line D_{M}, and a least significant bit (LSB) value of 0 stored in the MLC 101 is read out by the data line D_{L}. In this manner, the data stored in the MLC 101 (i.e., “10”), can be read.

Thereafter, when the first and second sensing signals Φ_{L} and Φ_{M} become logic low, the first and second sense amplifiers SA_{L} and SA_{M} become inactive. When the gate selection signal TG becomes logic high again, the bitline BL_A and the bitline BL_B are connected to each other, and the bitline BLB_A and the bitline BLB_B are connected to each other. The bitlines BL_B and BLB_B are half as long as the bitlines BL_A and BLB_A. Thus, when the bitline BL_A, which has a voltage of 0 V, is share-charged with the bitline BL_B, which has the voltage Vca, a voltage ⅔Vca is generated on the bitline BL_B. The voltage ⅔Vca is then stored in the capacitor Cs of the MLC 101, which means the original “10” data is refreshed. Thereafter, when the wordline WL2ₘ₊₁ is inactivated, the aforementioned sensing operation is terminated.

As will be understood by those skilled in the art, a multi-level DRAM may include defective cells. In order to replace such defective cells, a plurality of redundancy cells are needed. FIG. 2 is a circuit diagram of a conventional multi-level DRAM 300, which includes a normal MLC array 100 and a redundant MLC array 200. Referring to FIG. 2, the redundant MLC array 200 has the same structure as the normal MLC array 100 illustrated in FIG. 1.

MLCs only have half as much of a sensing margin as single-level cells (SLCs), and are thus are more likely to be identified as being defective than SLCs. In the multi-level DRAM 300, when MLCs in the normal MLC array 100 are determined as being defective, they are replaced with multi-level redundancy cells of the redundant MLC array 200. However, the multi-level redundancy cells that replace the defective MLCs of the normal MLC array 100 have the same relatively low sensing margin. This means that redundancy cells have a relatively high likelihood of being judged as defective, which causes the yield of multi-level DRAMS to be relatively low.

### SUMMARY OF THE INVENTION

Embodiments of the present invention include an integrated circuit memory device having redundancy memory cells therein. According to some of these embodiments, a memory device includes a first memory array having a plurality of rows and columns of multi-bit memory cells therein. In some cases, these multi-bit memory cells may be 2-bit dynamic random access memory (DRAM) cells. The memory device also includes a redundant memory array having a plurality of single-bit memory cells therein. These single-bit memory cells are configured to support replacement of a first plurality of multi-bit memory cells within the first memory array, in response to detecting at least one defective multi-bit memory cell within the first plurality of multi-bit memory cells. This first plurality of multi-bit memory cells may be a column or row of multi-bit memory cells containing at least one defective multi-bit memory cell therein.

According to some additional embodiments of the present invention, the plurality of single-bit memory cells are arranged as a least significant bit (LSB) column of single-bit memory cells and a most significant bit (MSB) column of single-bit memory cells. In these embodiment, a first column of multi-bit memory cells may include a first pair of differential bit lines, which are each divided into corresponding first and second bit line segments (e.g., (BL_A, BL_B), (BLB_A, BLB_B)), and a first pair of transmission gates (T1) that electrically couple corresponding ones of the first and second bit line segments together in response to an asserted transmission gate signal (TG). In this case, a pair of differential bit lines associated with the LSB column of single-bit memory cells are continuous bit lines that are uninterrupted by transmission gates.

According to still further embodiments of the present invention, a method of operating an integrated circuit memory device may include testing a first memory array having a plurality of rows and columns of multi-bit memory cells therein to detect a presence of at least one defective multi-bit memory cell in the first memory array. A step is then performed to replace a plurality of multi-bit memory cells, including the defective multi-bit memory cell, with a plurality of single-bit memory cells. This replacing step may include replacing a column of multi-bit memory cells including the defective multi-bit memory cell with at least two columns of single-bit memory cells.

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit diagram of a conventional multi-level dynamic random access memory (DRAM), which includes a plurality of multi-level cells (MLCs) each storing 2-bit data;

FIG. 2 is a circuit diagram of a conventional multi-level DRAM, which includes a MLC array and a redundant MLC array;

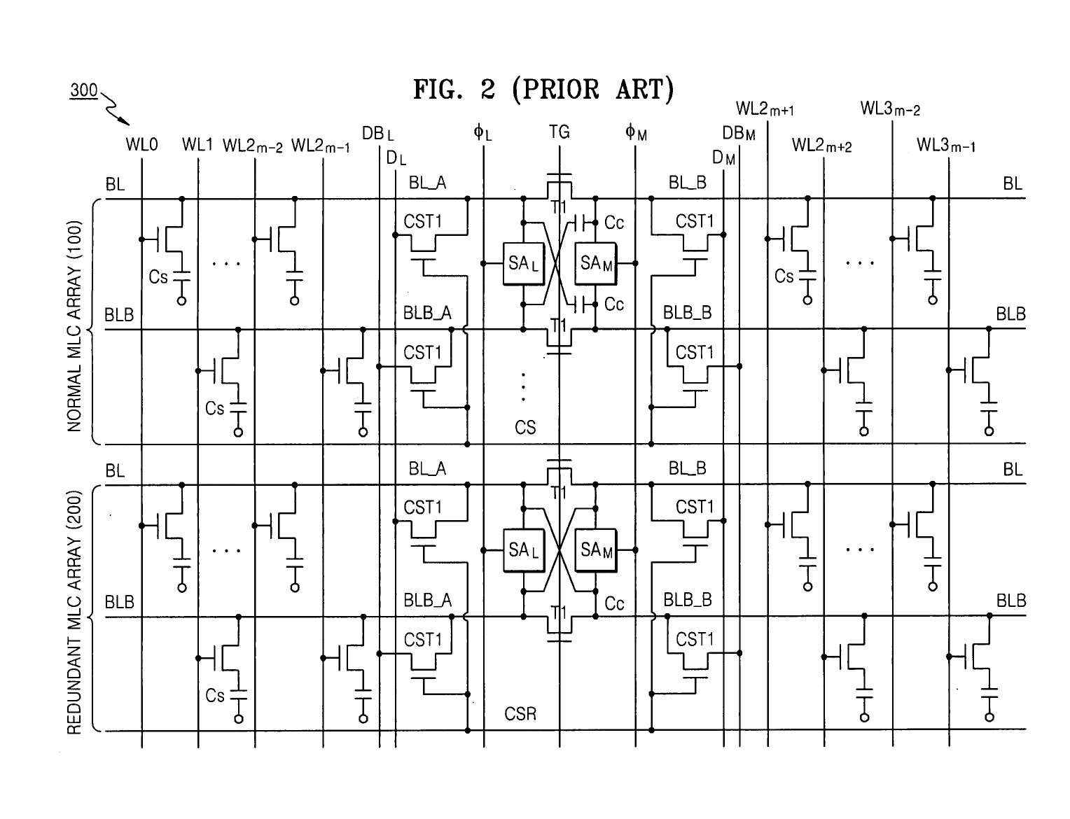

FIG. 3 is a circuit diagram illustrating a multi-level DRAM according to an embodiment of the present invention; and

FIG. 4 is a schematic diagram illustrating an X8 data input/output circuit of the multi-level DRAM illustrated in FIG. 3.

### DETAILED DESCRIPTION OF THE INVENTION

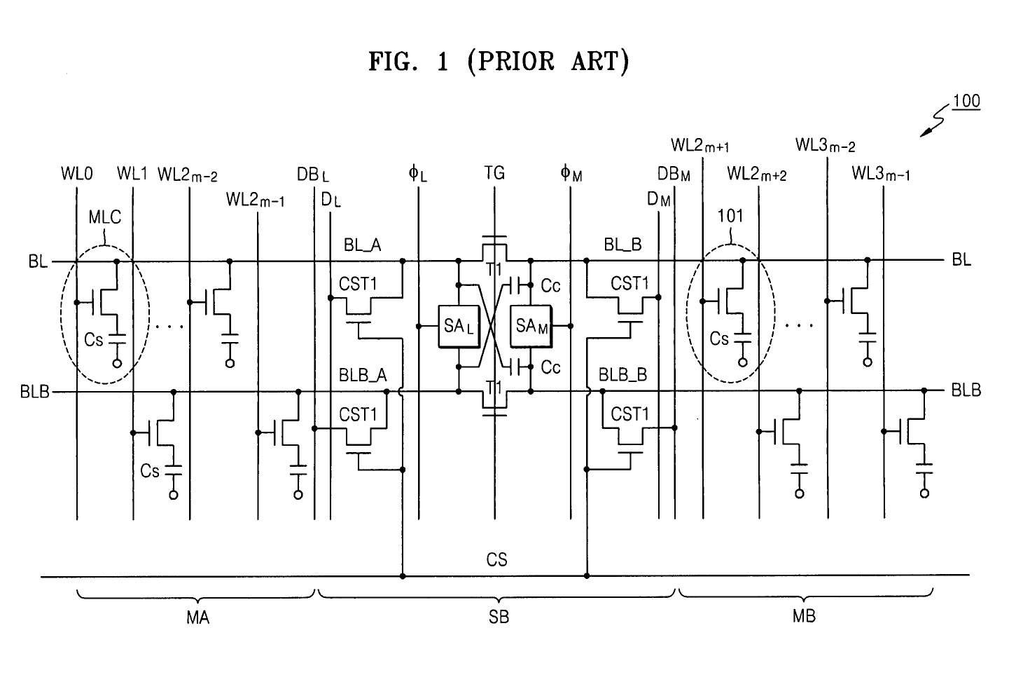

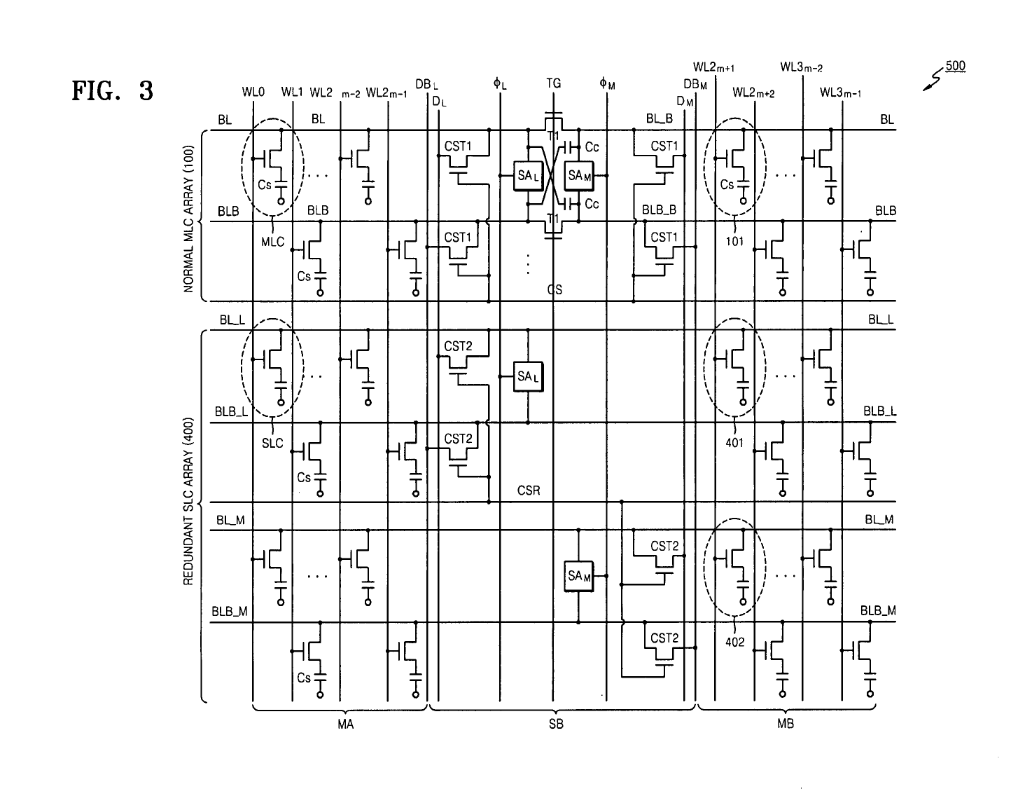

FIG. 3 is a circuit diagram of a multi-level dynamic random access memory (DRAM) 500 according to an exemplary embodiment of the present invention. Referring to FIG. 3, the multi-level DRAM 500 includes a normal MLC (MLC) array 100 and a redundant SLC (SLC) array 400. The normal MLC array 100 has the same structure as the multi-cell array 100 illustrated in FIG. 1, and thus, for convenience, a detailed description of the normal MLC array 100 will be skipped.

The redundant SLC array 400 includes a plurality of redundancy cells, which can replace defective cells in the normal MLC array 100. In general, a method of replacing defective cells is classified as a column redundancy method in which a column of cells including a defective cell is replaced with a column of redundancy cells or a row redundancy method in which a row of cells including a defective cell is replaced with a row of redundancy cells. In the current embodiment of the present invention, the column redundancy method is used. In this method, a pair of bitlines BL and BLB in the normal MLC array 100 is replaced by a pair of least significant bit (LSB) bitlines BL_L and BLB_L and a pair of most significant bit (MSB) bitlines BL_M and BLB_M in the redundant SLC array 400.

A block MA of the redundant SLC array 400 includes a plurality of SLCs, which are respectively located in the space between the intersections of a plurality of wordlines WL0, WL1, . . . , WL2ₘ₋₂, and WL2ₘ₋₁ and the bitlines BL_L, BLB_L, BL_M, and BLB_M. In the block MA, a total of m SLCs is connected to each of the bitlines BL_L, BLB_L, BL_M, and BLB_M. A block MB of the redundant SLC array 400 includes a plurality of SLCs, which are respectively located in the space between the intersections of a plurality of wordlines WL2ₘ₊₁, WL2ₘ₊₂, . . . , WL3ₘ₋₂, and WL3ₘ₋₁ and the bitlines BL and BLB. In the block MB, a total of m/2 SLCs are connected to each of the bitlines BL_L, BLB_L, BL_M, and BLB_M.

In a block SB of the redundant SLC array 400, a first sense amplifier SA_{L}, which is controlled by a first sensing signal Φ_{L}, is connected between the LSB bitlines BL_L and BLB_L, and a second sense amplifier SA_{M}, which is controlled by a second sensing signal Φ_{M}, is connected between the MSB bitlines BL_M and BLB_M. The first sense amplifier SA_{L} is connected to data lines DB_{L} and D_{L} via a plurality of transistors CST2, which are controlled by a redundancy column selection signal CSR. The second sense amplifier SA_{M} is connected to data lines DB_{M} and D_{M} via a plurality of transistors CST2, which are controlled by the redundancy column selection signal CSR. The first and second sense amplifiers SA_{L} and SA_{M} are illustrated in FIG. 3 as being located in the vicinity of the blocks MA and MB, respectively. However, the present invention is not restricted to it. In other words, the first and second sense amplifiers SA_{L} and SA_{M} may be both located near to either the block MA or MB.

The operation of the multi-level DRAM 500 will now be described in detail. When the normal MLC array 100 does not include any defective cells (i.e., when none of the MLCs 101 in the normal MLC array 100 are defective), the wordline WL2ₘ₊₁ is activated and the second sense amplifier SA_{M} in the block SB of the normal MLC array 100 is enabled by the second sensing signal Φ_{M}. Then, MSB data stored in the MLC 101 is transmitted by the bitline BL_B. Thereafter, a first sense amplifier SA_{L} in the block SB of the normal MLC array 100 is enabled by the first sensing signal Φ_{L}. Then, LSB data stored in the MLC 101 is transmitted by the bitline BL_A. The MSB data transmitted by the bitline BL_B is output via the data line D_{M}, and the LSB data transmitted by the bitline BL_A is output via the data line D_{L}.

On the other hand, when the normal MLC array 100 includes at least one defective cell, the wordline WL2ₘ₊₁ is activated, and the second sense amplifier SA_{M} is enabled by the second sensing signal Φ_{M}. Then, data stored in a redundancy SLC 402 in the redundant SLC array 400 is transmitted by the bitline BL_M. The data stored in the redundancy SLC 402 corresponds to the MSB data stored in the MLC 101. In this case, no sensing operation is performed on the bitlines BL_L and BLB_L.

Thereafter, the first sense amplifier SA_{L} is enabled by the first sensing signal Φ_{L} and thus begins to operate. Then, data stored in a redundancy SLC 401 in the redundant SLC array 400 is transmitted by the bitline BL_L. The data stored in the redundancy SLC 401 corresponds to the LSB data stored in the MLC 101. In this case, no sensing operation is performed on the bitlines BL_M and BLB_M. Thereafter, when the redundancy column selection signal CSR is activated, the data transmitted by the bitline BL_M is output via the data line D_{M}, and the data transmitted by the bitline BL_L is output via the data line D_{L}.

In this case, the normal MLC array 100 and the redundant SLC array 400 are consecutive in terms of the order in which the first and second sensing signals Φ_{L} and Φ_{M} are applied to the first and second sense amplifiers SA_{L} and SA_{L}, respectively, and the operations of the data lines DB_{M}, D_{M}, DB_{L}, and D_{L}. Thus, the multi-level DRAM 500 does not need an additional control circuit for controlling the operation of the redundant SLC array 400.

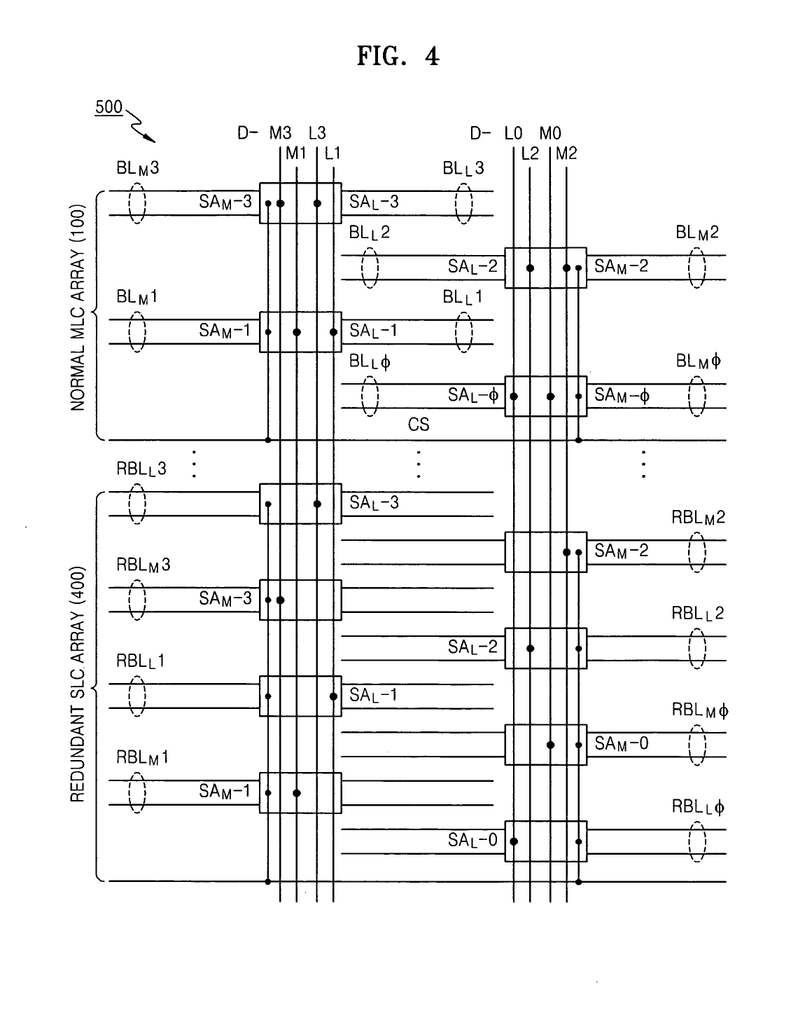

FIG. 4 is a schematic diagram illustrating an X8 data input/output circuit of the multi-level DRAM 500 illustrated in FIG. 3. Referring to FIG. 4, an MLC of the normal MLC array 100 comprises 4 bitline pairs BL0, BL1, BL2, and BL3. Reference characters SA_{M}-0 through SA_{M}-3 indicate MSB sense amplifiers, and reference characters SA_{L}-0 through SA_{L}-3 indicate LSB sense amplifiers. MSB data of bitlines BL_{M}0, BL_{M}1, BL_{M}2, and BL_{M}3 is input/output via data lines D-M0 through D-M3. LSB data of bitlines BL_{L}0, BL_{L}1, BL_{L}2, and BL_{L}3 is input/output via data lines D-L0 through D-L3. For convenience, the data lines D-M0 through D-M3 and D-L0 through D-L3 are connected to the bitlines BL_{M}0, BL_{M}1, BL_{M}2, and BL_{M}3, and BL_{L}0, BL_{L}1, BL_{L}2, and BL_{L}3, respectively. Complementary bitlines BLB_{M}0, BLB_{M}1, BLB_{M}2, BLB_{M}3, BLB_{L}0, BLB_{L}1, BLB_{L}2, and BLB_{L}3, which are also connected to the data lines D-M0 through D-M3 and D-L0 through D-L3, respectively, are not illustrated in FIG. 4.

In the normal MLC array 100, MSB data of the complementary bitlines BLB_{M}0, BLB_{M}1, BLB_{M}2, and BLB_{M}3 is output via the data lines D-M0 to D-M3, and LSB data of the complementary bitlines BLB_{L}0, BLB_{L}1, BLB_{L}2, and BLB_{L}3 is output via the data lines D-L0 to D-L3. Accordingly, a total of 8-bit data is output.

A single-level redundancy cell of the redundant SLC array 400 comprises 8 redundant bitline pairs RBL_{L}0, RBL_{M}0, RBL_{L}1, RBL_{M}1, RBL_{L}2, RBL_{M}2, RBL_{L}3, and RBL_{M}3. The redundant bitline pair RBL_{L}0 is connected to the LSB sense amplifier SA_{L}-0, the redundant bitline pair RBL_{M}0 is connected to the MSB sense amplifier SA_{M}-0, the redundant bitline pair RBL_{L}1 is connected to the LSB sense amplifier SA_{L}-1, the redundant bitline pair RBL_{M}1 is connected to the MSB sense amplifier SA_{M}-1, the redundant bitline pair RBL_{L}2 is connected to the LSB sense amplifier SA_{L}-2, the redundant bitline pair RBL_{M}2 is connected to the MSB sense amplifier SA_{M}-2, the redundant bitline pair RBL_{L}3 is connected to the LSB sense amplifier SA_{L}-3, and the redundant bitline pair RBL_{M}3 is connected to the MSB sense amplifier SA_{M}-3. Data of the redundant bitline pairs RBL_{M}0, RBL_{M}1, RBL_{M}2, and RBL_{M}3 is output via the data lines D-M0 to D-M3, and data of the redundant bitline pairs RBL_{L}0, RBL_{L}1, RBL_{L}2, and RBL_{L}3 is output via the data lines D-L0 to D-L3.

As described above, data of an MLC of the normal MLC array 100 is read out as MSB data and LSB data by performing a sensing operation twice, whereas data of a single-level redundancy cell of the redundant SLC array 400 is read out by performing a sensing operation only once. A single-level redundancy cell is not sensed while LSB data of a multi-level main cell is sensed.

Single-level redundancy cells have only half as much storage capacity as multi-level main cells. Therefore, the redundant SLC array 400 must be twice as large as the normal MLC array 100. However, single-level redundancy cells have twice as much sensing margin as multi-level main cells. Therefore, single-level redundancy cells are less likely to be determined as being defective due to a higher sensing margin than multi-level main cells. Accordingly, a multi-level DRAM, which replaces defective cells in the normal MLC array 100 with single-level redundancy cells in the redundant SLC array 400, is less likely to be determined as being defective. Therefore, it is possible to enhance the yield of multi-level DRAMs. Even though the area of a multi-level DRAM is increased by 1% when installing the redundant SLC array 400 in the multi-level DRAM, it is effective to use single-level redundancy cells to replace defective cells in the normal MLC array 100 if the use of the single-level redundancy cells can offer a yield gain of 1% or higher.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An integrated circuit memory device, comprising:
a first memory array having a plurality of rows and columns of multi-bit memory cells therein; and
a redundant memory array having a plurality of single-bit memory cells therein that are configured to support replacement of a first plurality of multi-bit memory cells within said first memory array, in response to detecting at least one defective multi-bit memory cell within the first plurality of multi-bit memory cells.

2. The memory device of claim 1, wherein the multi-bit memory cells are 2-bit memory cells; and wherein the plurality of single-bit memory cells are arranged as a least significant bit (LSB) column of single-bit memory cells and a most significant bit (MSB) column of single-bit memory cells.

3. The memory device of claim 2, wherein a first column of multi-bit memory cells in said first memory array includes a first pair of differential bit lines, which are each divided into corresponding first and second bit line segments, and a first pair of transmission gates that electrically couple corresponding ones of the first and second bit line segments together in response to an asserted transmission gate signal.

4. The memory device of claim 3, wherein a pair of differential bit lines associated with the LSB column of single-bit memory cells are continuous bit lines that are uninterrupted by transmission gates.

5. The memory device of claim 2, wherein a layout area associated with the LSB and MSB columns of single-bit memory cells is about two times a layout area associated with a column of multi-bit memory cells in said first memory array.

6. An integrated circuit memory device, comprising:
a first memory array having a plurality of rows and columns of multi-bit DRAM cells therein; and
a redundant memory array having a plurality of single-bit DRAM cells therein that are configured to support replacement of a first plurality of multi-bit DRAM cells within said first memory array, in response to detecting at least one defective multi-bit DRAM cell within the first plurality of multi-bit DRAM cells.

7. The memory device of claim 6, wherein the multi-bit DRAM cells are 2-bit DRAM cells; and wherein the plurality of single-bit DRAM cells are arranged as a least significant bit (LSB) column of single-bit DRAM cells and a most significant bit (MSB) column of single-bit DRAM cells.

8. The memory device of claim 6, wherein a layout area associated with the LSB and MSB columns of single-bit DRAM cells is about two times a layout area associated with a column of multi-bit DRAM cells in said first memory array.

9. A method of operating an integrated circuit memory device, comprising the steps of:
testing a first memory array having a plurality of rows and columns of multi-bit memory cells therein to detect a presence of at least one defective multi-bit memory cell in the first memory array; and
replacing a plurality of multi-bit memory cells including the defective multi-bit memory cell with a plurality of single-bit memory cells.

10. The method of claim 9, wherein said replacing step comprises replacing a column of multi-bit memory cells including the defective multi-bit memory cell with at least two columns of single-bit memory cells;

11-34. (canceled)
